(19) United States
(12) Patent Application Publication
(10) Pub. No.: US 2013/0078747 A1
(43) Pub. Date: Mar. 28, 2013

(54) SUBSTRATE ETCHING METHOD AND SUBSTRATE ETCHING APPARATUS

(71) Applicant: Tokyo Electron Limited, Minato-ku (JP)

(72) Inventors: Haruo IWATSU, Koshi-shi (JP); Shigenori Kitahara, Koshi-shi (JP); Masatoshi Shiraishi, Koshi-shi (JP)

(73) Assignee: Tokyo Electron Limited, Minato-ku (JP)

(21) Appl. No.: 13/679,136

(22) Filed: Nov. 16, 2012

Related U.S. Application Data
(63) Continuation of application No. PCT/JP2011/060049, filed on Apr. 25, 2011.

(30) Foreign Application Priority Data
May 19, 2010 (JP) 2010-115026

(51) Int. Cl. H01L 21/67

(52) U.S. Cl. CPC H01L 22/12; H01L 21/67075
USPC 438/17; 156/345.19; 156/345.15

(57) ABSTRACT

A method for selectively etching a substrate includes providing a template having opening portions formed on an upper surface in a predetermined pattern and flow channels penetrating through the template from the opening portions to a lower surface of the template, filling an etching solution into the flow channels, coupling the upper surface of the template to a substrate such that the opening portions correspond to the predetermined pattern of through holes to be formed through the substrate, and supplying the etching solution onto the substrate through the opening portions of the template such that the through holes are etched through the substrate.

### CROSS-REFERENCE TO RELATED APPLICATIONS

This application is a continuation of International Application No. PCT/JP2011/060049, filed Apr. 25, 2011, which is based upon and claims the benefit of priority from Japanese Application No. 2010-115026, filed May 19, 2010. The entire contents of these applications are incorporated herein by reference.

### BACKGROUND OF THE INVENTION

1. Field of the Invention

The present invention relates to a method for etching a substrate to form a predetermined through hole in the substrate by performing an etch process on the substrate, to a method for selectively processing a substrate to form a deposited film in a through hole in the substrate by performing a deposition process on the substrate, and to an selective etching apparatus.

2. Description of Background Art

In the manufacture of semiconductor devices (hereinafter referred to as devices), the devices are becoming even more highly integrated in recent years. In the meantime, when fabricating products by connecting multiple highly integrated devices through wiring, problems have occurred such as longer wiring lengths, thus causing an increase in wiring resistance and wiring delays.

To solve such problems, three-dimensional integration technologies are proposed to laminate devices three dimensionally. In such a three-dimensional integration technology, fine through holes (H), so-called TSVs (through silicon vias), with a diameter of 100 μm or smaller, for example, are formed in a thin-film semiconductor wafer (W) (hereinafter referred to as a wafer) with circuit 300 formed on its surface as shown in FIG. 17(a), for example. Then, connection electrodes 301 are formed in such through holes (H), and vertically laminated wafers (W) are electrically connected by their respective connection electrodes 301 as shown in FIG. 17(b) (Japanese Laid-Open Patent Publication No. 2009-004722, for example).

Here, high positional accuracy is required for the above-described through holes (H). Thus, when forming through holes (H), a mask is formed using photolithographic techniques, for example, and a wafer (W) with such a mask is etched through so-called dry etching such as plasma etching to form through holes (H). Also, instead of dry etching, as for a method for conducting fine processes on a local region through wet etching, the following is proposed as described in Japanese Laid-Open Patent Publication No. 2008-280558: a puddle of etching solution is formed on a surface of a wafer (W); the tips of microprobes are dipped into the puddle of etching solution; and electric current is flowed from the microprobes to the wafer (W) to control the etching region so that the etching is conducted highly precisely. The entire contents of these publications are incorporated herein by reference.

### SUMMARY OF THE INVENTION

According to one aspect of the present invention, a method for selectively etching a substrate includes providing a template having opening portions formed on an upper surface in a predetermined pattern and flow channels penetrating through the template from the opening portions to a lower surface of the template, filling an etching solution into the flow channels, coupling the upper surface of the template to a substrate such that the opening portions correspond to the predetermined pattern of through holes to be formed through the substrate, and supplying the etching solution onto the substrate through the opening portions of the template such that the through holes are etched through the substrate.

According to another aspect of the present invention, a method for selectively processing a substrate includes providing a template having opening portions formed on an upper surface in a predetermined pattern and flow channels penetrating through the template from the opening portions to a lower surface of the template, coupling the upper surface of the template to a substrate having through holes formed through the substrate such that the opening portions correspond to the predetermined pattern of the through holes in the substrate, and supplying a processing solution into the through holes formed in the substrate through the opening portions of the template such that the processing solution deposits films in the through holes, respectively.

According to yet another aspect of the present invention, a selective etching apparatus includes a processing vessel, a template accommodated in the processing vessel and having opening portions formed on an upper surface of the template and flow channels penetrating through the template from the opening portions to a lower surface of the template, and a mounting base which is accommodated in the processing vessel and mounts a substrate and the template. The flow channels of the template is formed to be filled with an etching solution, the opening portions are positioned on the upper surface in a predetermined pattern, and the upper surface of the template is formed to be coupled to a surface of the substrate such that the opening portions correspond to the predetermined pattern of through holes to be formed through the substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view schematically showing a structure of a substrate processing system to carry out a method for supplying a process solution according to an embodiment;

FIG. 2 is a vertical cross section showing a state where a wafer and a support sheet are laminated;

FIG. 3 is a horizontal cross section schematically showing the structure of a process solution supply apparatus;

FIG. 4 is a vertical cross section schematically showing the structure of a process solution supply apparatus;

FIG. 5 is a view schematically illustrating the structure of a template;

FIG. 6 is a vertical cross section schematically showing the structure in the vicinities of flow channels of a template;

FIG. 7 is a horizontal cross section schematically showing the structure of the vicinity of a flow channel;

FIG. 8 is a vertical cross section schematically showing the structure of a selective etching apparatus;

FIG. 9 is a flowchart of wafer processing including the etching method according to the present embodiment;

FIG. 10(a)-10(i) are views showing wafer processing including the etching method according to the present embodiment, 10(a) being a view where a wafer is etched, 10(b) being a view where an etching solution is filled in the flow channels of a template, 10(c) being a view where the wafer is coupled to the template, 10(d) being a view where covers are opened, 10(e) being a view where through holes are formed in the wafer, 10(f) being a view where the wafer and the template are coupled again, 10(g) being a view where insulation film is formed on through holes, 10(h) being a view where the insulation film on the bottoms of through holes is selectively removed, and 10(i) being a view where metal film and connection electrodes are formed;

FIG. 11 is a vertical cross section showing where wafers are laminated;

FIG. 12 is a view illustrating positions of vibration mechanisms according to another embodiment;

FIG. 13 is a view illustrating positions of vibration mechanisms according to yet another embodiment;

FIG. 14 is a view illustrating positions of vibration mechanisms according to yet another embodiment;

FIG. 15 is a view illustrating positions of vibration mechanisms according to yet another embodiment;

FIG. 16 is a view illustrating a state where the lower surface of a template is covered by a water sealing film; and

FIG. 17(a)-17(b) are views illustrating a thin-film wafer and a state where thin-film wafers are laminated.

### DETAILED DESCRIPTION OF THE EMBODIMENTS

The embodiments will now be described with reference to the accompanying drawings, wherein like reference numerals designate corresponding or identical elements throughout the various drawings.

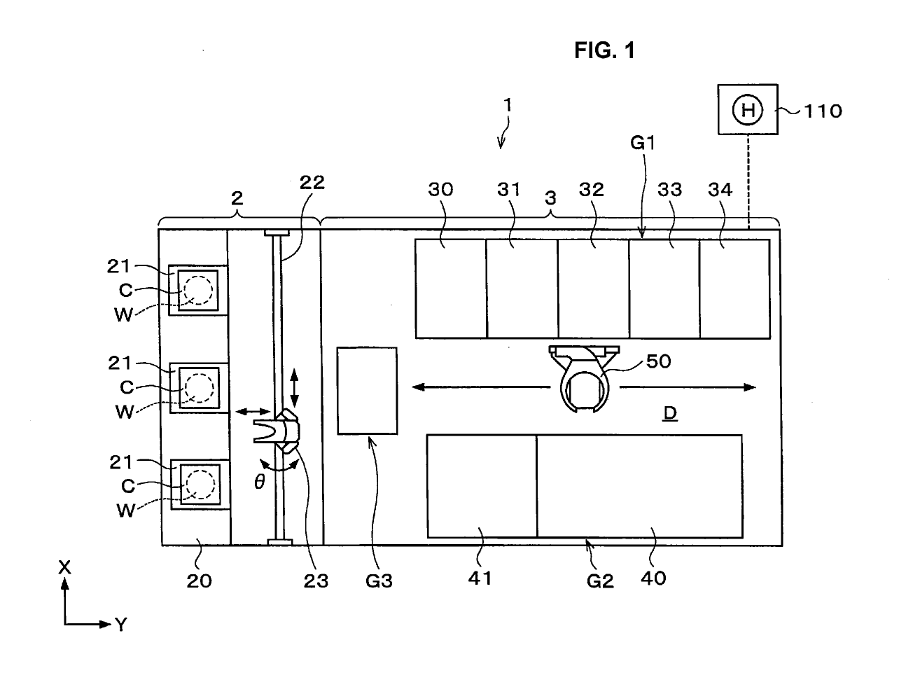

FIG. 1 is a plan view schematically showing the structure of substrate processing system 1, where a process solution supply apparatus is provided to implement a method for supplying process solutions according to the present embodiment.

Substrate processing system 1 is structured by integrating the following: cassette station 2 to handle multiple wafers (W), where a support sheet is laminated using a wafer lamination apparatus (not shown in the drawing) provided outside, for example, (hereinafter they may be simply referred to as wafers (W)), by transferring wafers (W) one each on a cassette (C) to and from substrate processing system 1, as well as by transferring each wafer (W) to and from a cassette (C) as shown in FIG. 1, for example; and processing station 3 where various processing apparatuses are provided to conduct predetermined processes on wafers (W).

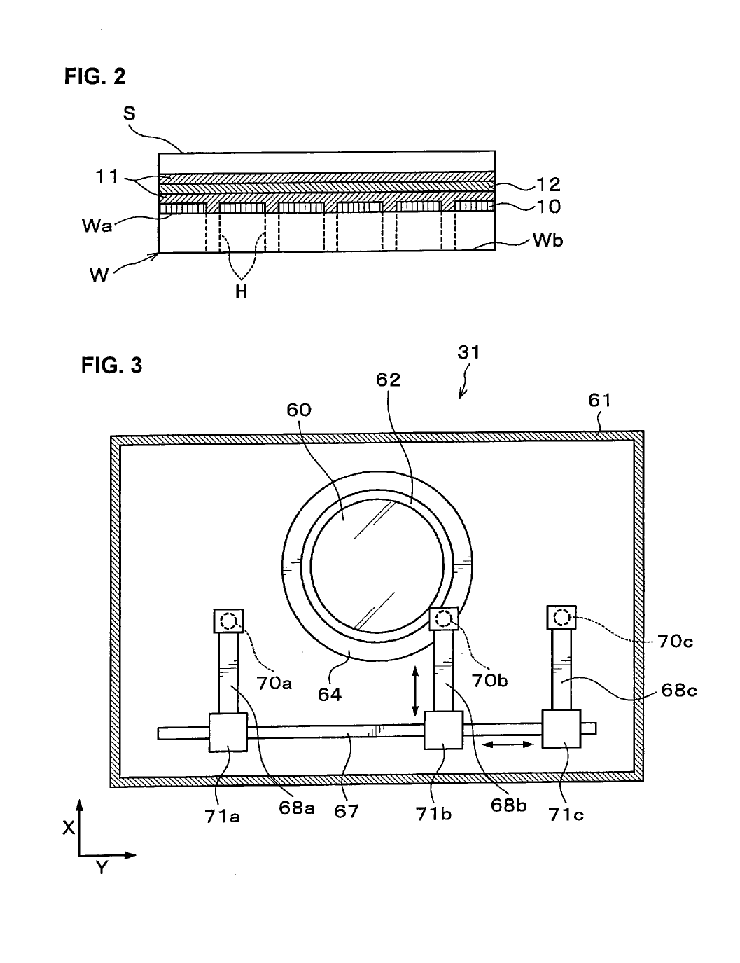

A method for etching a wafer (W) is described according to the present embodiment by an example using a wafer (W) where insulation film 10 is coated on its upper surface (Wa), metal layer 11 and insulation layer 12 are laminated on top of insulation film 10, and predetermined circuits are formed in such a structure as shown in FIG. 2, for example. Metal layer 11 laminated on a wafer (W) is in contact with the wafer (W) by penetrating through predetermined positions of insulation film 10. Such positions where metal layer 11 and a wafer (W) are in contact while penetrating through the wafer (W) are used for forming fine through holes (H), called TSVs in a three-dimensional integration technology. Here, those positions designed to form through holes (H) correspond to predetermined positions to which process solutions are supplied in the present invention. A support sheet (S) made of glass substrate or the like is laminated on metal layer 11. In substrate processing system 1, a wafer (W) is accommodated in a cassette (C) in such a way that the support sheet (S) is positioned under the wafer (W), namely, lower surface (Wb) of the wafer (W) faces upward. FIG. 2 is a view where two metal layers 11 and one insulation layer 12 are alternately laminated; however, the number of metal layers 11 and insulation layers 12 as well as their structures are determined freely.

In cassette station 2, cassette mounting base 20 is provided, and three cassette mounting plates 21, for example, are provided on cassette mounting base 20. Cassette mounting plates 21 are aligned in horizontal directions X (vertical directions in FIG. 1). Such multiple cassette mounting plates 21 are used to mount cassettes (C) when cassettes (C) are transferred between substrate processing system 1 and the outside.

Wafer transfer apparatus 23, which moves freely along transfer route 22 extending in directions X, is provided in cassette station 2 as shown in FIG. 1. Wafer transfer apparatus 23 is also movable in vertical directions as well as around the vertical axis (directions θ), and transfers a wafer (W) between a cassette (C) on each cassette mounting plate 21 and a transit apparatus (not shown in the drawing) in third block (G3) of later-described processing station 3.

In processing station 3 adjacent to cassette station 2, multiple, for example, three blocks (G1, G2, G3) with various apparatuses are provided. For example, first block (G1) is provided on the rear side of processing station 3 (in plus direction X in FIG. 1), and second block (G2) is provided on the front side of processing station 3 (in minus direction X in FIG. 1). In addition, third block (G3) is provided on a side of processing station 3 where cassette station 2 is positioned (in minus direction Y in FIG. 1).

For example, in first block (G1), the following are positioned from the side of cassette station 2 in the order in which they are described here: overall etching apparatus 30 to etch the lower surface of a wafer (W) to a predetermined depth; process solution supply apparatus 31 to supply an etching solution as a process solution at predetermined positions of lower surface (Wb) of the wafer (W) etched to a predetermined depth; selective etching apparatus 32 to selectively etch the wafer (W) using the supplied etching solution; insulation film forming apparatus 33 to form insulation film on the selectively etched wafer (W); and insulation film removing apparatus 34 to selectively remove the insulation film formed on the wafer (W).

For example, in second block (G2), the following are positioned from the side of cassette station 2 in the opposite order from which they are described here; metal film deposition apparatus 40 to form metal film on lower surface (Wb) of a wafer (W); and electrode forming apparatus 41 to form connection electrodes on the wafer (W).

For example, in third block (G3), a transit apparatus (not shown in the drawing) is provided so that apparatuses for transferring a wafer (W) are switched between wafer transfer apparatus 23 and later-described wafer transfer apparatus 50.

As shown in FIG. 1, a wafer transfer region (D) is formed in a region surrounded by first block (G1)˜third block (G3). Wafer transfer apparatus 50, for example, is positioned in the wafer transfer region (D).

Wafer transfer apparatus 50 has a transfer arm that is movable in directions Y, directions X, directions θ and vertical directions, for example. Wafer transfer apparatus 50 moves in the wafer transfer region (D) to transfer a wafer to a predetermined apparatus in its surrounding first block (G1) or second block (G2).

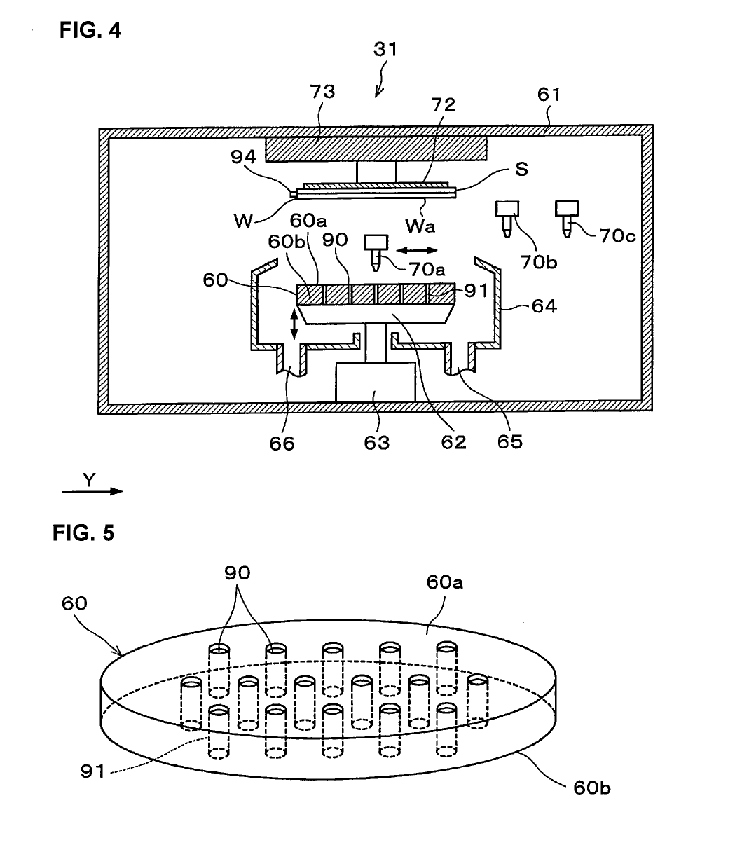

Next, the structure of above-described process solution supply apparatus 31 is described. FIG. 3 is a horizontal cross section schematically showing the structure of process solution supply apparatus 31, and FIG. 4 is a vertical cross section schematically showing the structure of process solution supply apparatus 31.

As shown in FIGS. 3 and 4, the following are provided in process solution supply apparatus 31: process vessel 61 to accommodate template 60 to be used in the etching method of the present embodiment; and spin chuck 62 as a rotation holding section which is formed in process vessel 61 and rotates template 60 while holding it. Spin chuck 62 has drive mechanism 63 with a built-in motor (not shown in the drawing), for example, and is rotated at a predetermined speed by drive mechanism 63.

Cup 64 is provided around spin chuck 62 to receive and collect a process solution scattering or dripping from template 60. Drainpipe 65 to drain the collected solution and exhaust pipe 66 to release the atmosphere in cup 64 are connected to the lower surface of cup 64.

In minus direction X of cup 64 (on the lower side in FIG. 3), rail 67 is formed extending along directions Y (toward the right and left in FIG. 3) as shown in FIG. 3. Rail 67 is formed from the outer side of minus direction Y (toward the left in FIG. 3) of cup 64, for example, to the outer side of plus direction Y (toward the right in FIG. 3). Arms (68a, 68b, 68c) are attached to rail 67, and process solution supply nozzles (70a, 70b, 70c) are supported by their respective arms (68a, 68b, 68c) to discharge an etching solution, an insulation film electrocoating solution and an electrolytic plating solution respectively as process solutions. Arms (68a, 68b, 68c) are moved freely on rail 67 by nozzle drive sections (71a, 71b, 71c). Also, arms (68a, 68b, 68c) are elevated and lowered freely by nozzle drive sections (71a, 7b, 71c) so that the heights of process solution supply nozzles (70a, 70b, 70c) are adjusted.

Also, on the upper side of spin chuck 62, holding mechanism 72 is provided to support a wafer (W) with a laminated support sheet (S) in a way for lower surface (Wb) of the wafer (W) to face spin chuck 62, namely, to face template 60 supported on spin chuck 62. Holding mechanism 72 is supported at an upper end of process vessel 61, for example, by transport mechanism 73 which moves holding mechanism 72 vertically and horizontally.

As shown in FIGS. 4 and 5, for example, template 60 is a member in a substantially disc shape where multiple opening portions 90 are formed in a predetermined pattern on its upper surface (60a). Then, opening portions 90 formed in template 60 are positioned corresponding to where above-described metal layer 11 is in contact with a wafer (W), namely, where through holes (H), so-called TSVs in a three-dimensional integration technology, are to be formed. Flow channels 91 connected to opening portions 90 are formed inside template 60, and flow channels 91 are extended to lower surface (60b) of template 60. Here, template 60 is formed using insulative material which is tolerant to etching solutions for etching a wafer (W), for example. Silicon carbide (SiC) or the like may be used, for example.

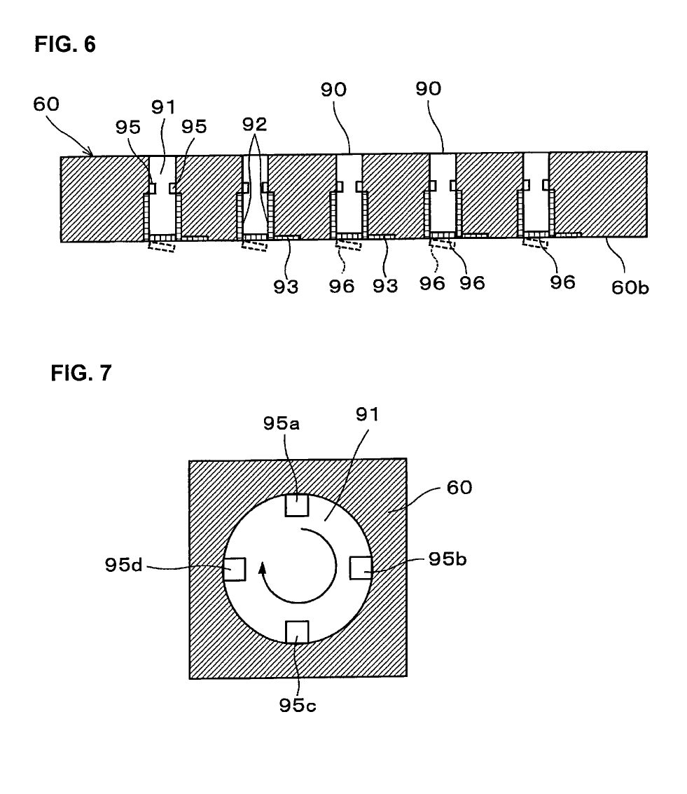

On the inner surface of flow channel 91 of template 60, metal film 92 as first electrode 92 is formed as shown in FIG. 6, for example. Part of metal film 92 is extended to lower surface (60b) of template 60, forming connection terminal 93 using the extended portion of metal film 92. In addition, such metal film 92 is formed to be positioned at a predetermined distance from opening portion 90 of template 60. Second electrode 94 to be paired to metal film 92 as first electrode 92 is provided to be electrically connected with metal layer 11 formed on upper surface (Wa) of a wafer (W) as shown in FIG. 4, for example. Second electrode 94 may be formed by being embedded in advance in a support sheet (S) to have electrical contact with metal layer 11 of a wafer (W), for example. Alternatively, second electrode 94 may be formed by using a conductive adhesive to laminate a wafer (W) and a support sheet (S), and by electrically connecting the adhesive and second electrode 94. As long as second electrode 94 is electrically connected with metal layer 11 of a wafer (W), any connection method may be employed. Also, first electrode 92 is formed using a metal that is tolerant to etching solutions.

In addition, as shown in FIG. 7, for example, four vibration mechanisms (95a-95d) are positioned circumferentially on a planar view in a region on the inner surface of flow channel 91 where metal film 92 is not formed. A pulse generator (not shown in the drawing) is electrically connected to vibration mechanisms 95, and the mechanisms are structured to vibrate independently of each other by receiving signals from the pulse generator. Here, the power source used to drive vibration mechanisms (95a-95d) is not limited to a pulse generator, and a high-frequency oscillator, for example, may also be used.

Covers 96 are each provided in a position on lower surface (60b) of template 60 corresponding to an end of flow channel 91 positioned opposite opening portion 90. Such cover 96 is structured to open and close freely as shown with broken lines in FIG. 6. Using a switching mechanism not shown in the drawing, cover 96 is operated to open or close by receiving electrical signals transmitted from later-described control unit 110 through connection terminal 93 made from metal film 92 formed on lower surface (60b) of template 60.

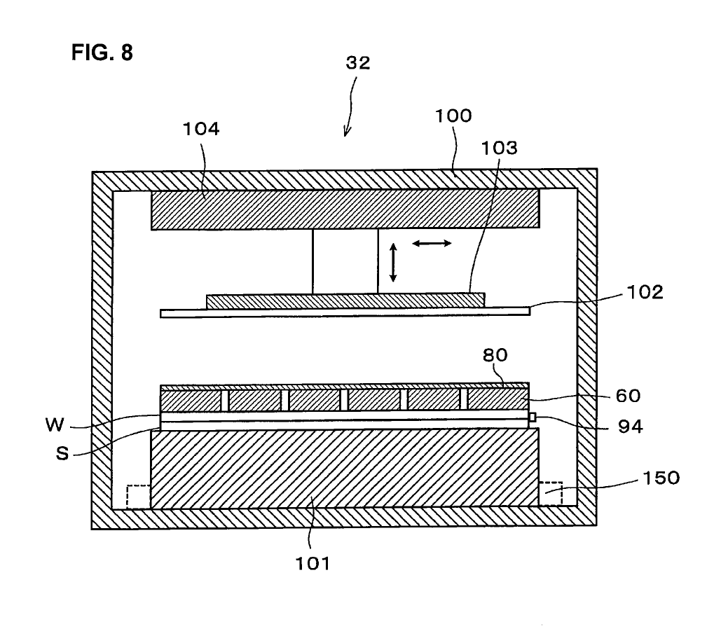

Next, selective etching apparatus 32 is described. As shown in FIG. 8, selective etching apparatus 32 has the following: process vessel 100 to accommodate template 60 and a wafer (W) in its inside; mounting base 101 to mount template 60 and a wafer (W); holding mechanism 103 to hold circuit board 102; and transport mechanism 104 to move holding mechanism 103 in vertical and horizontal directions. A vacuum chuck or the like is used as mounting base 101.

Circuit board 102 has functions to transmit electrical signals communicated between control unit 110 in substrate processing system 1 and connection terminals 93 formed on lower surface (60b) of template 60. Control unit 110 is a computer, for example, and has a program storage section (not shown in the drawing). Programs to supply an etching solution at selective etching apparatus 32, to control the power unit, and to monitor the current flow between first electrode 92 and second electrode 94 during etching, are stored in such a program storage section. In addition, the program storage section also stores other programs to implement later-described processes on wafers in substrate processing system 1 by controlling operations on drive mechanisms in the above-described various process apparatuses and transfer apparatuses. Here, it is an option to use programs stored in a computer readable recording medium (H) such as a hard disc (HD), flexible disc (FD), compact disc (CD), magneto-optical disc (MO) or memory card, and to install such programs in control unit 110 from the memory medium.

Since insulation film forming apparatus 33 and electrode forming apparatus 41 have the same structure as selective etching apparatus 32, their descriptions are omitted here.

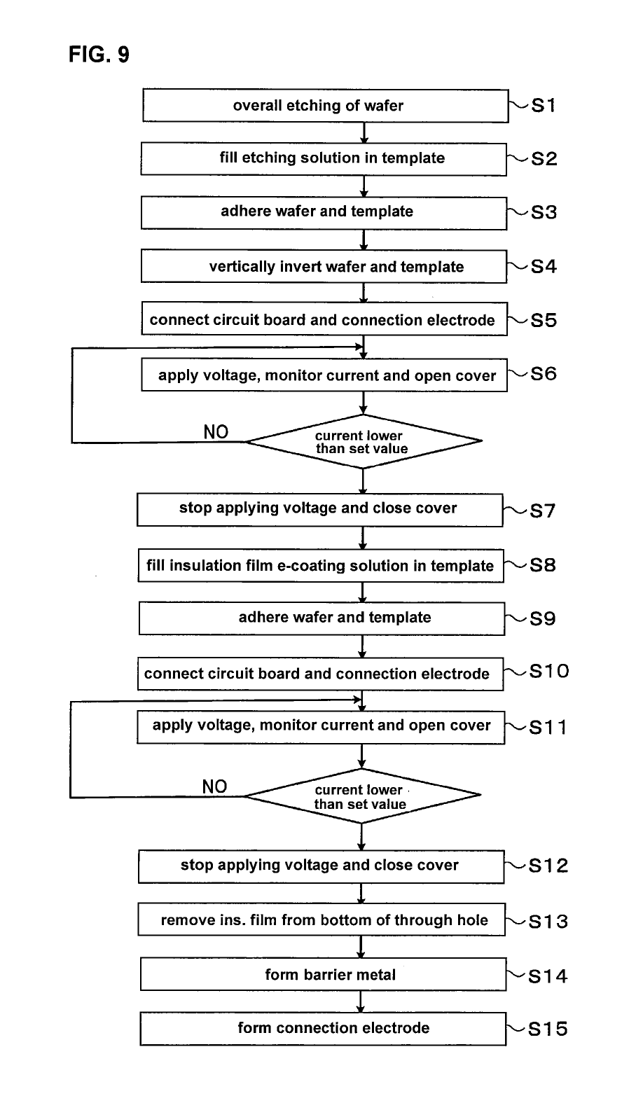

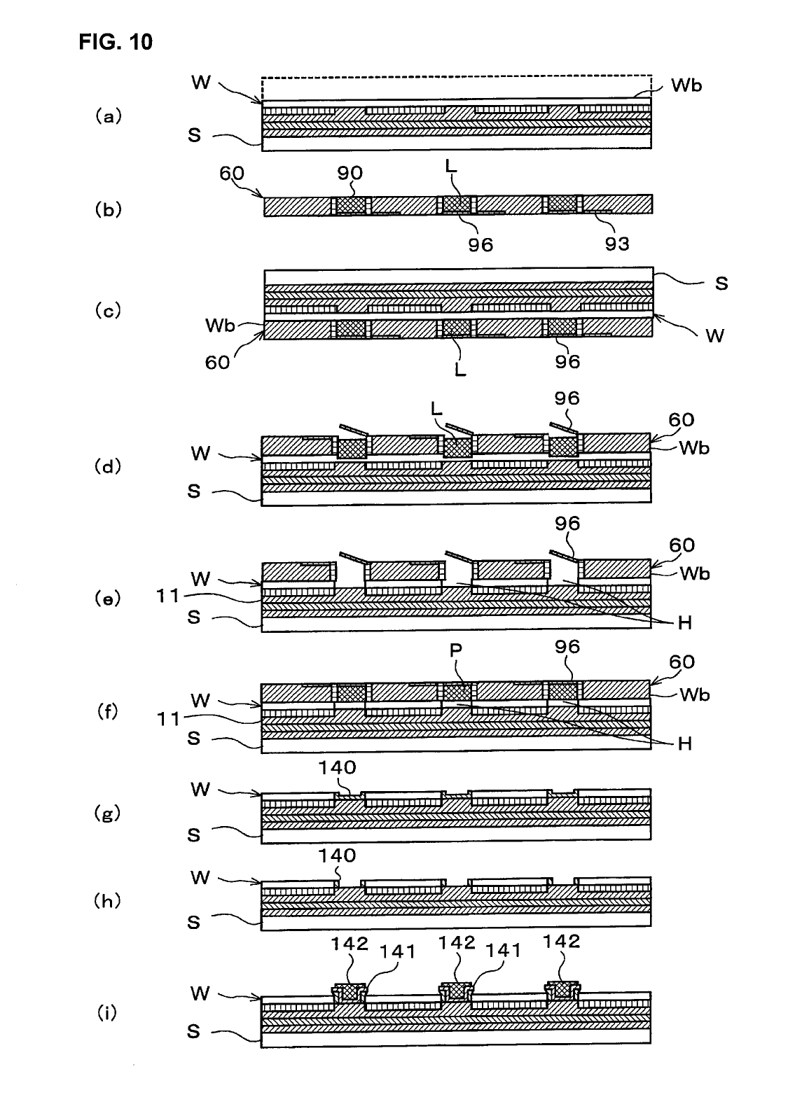

Next, a method for processing a wafer (W) is described using substrate processing system 1 described above. FIG. 9 is a flowchart showing an example of main steps in a method for processing a wafer (W), and FIG. 10 schematically shows views illustrating a wafer (W) in each step.

First, multiple wafers (W) with support sheets (S) laminated by a lamination apparatus (not shown in the drawing) provided outside substrate processing system 1 are accommodated in cassettes (C), and then cassettes (C) are mounted on predetermined cassette mounting plates 21 in cassette station 2. Next, a wafer (W) in a cassette (C) is taken out by wafer transfer apparatus 23 and transferred to overall etching apparatus 30 by wafer transfer apparatus 50 via a transit apparatus provided in third block (G3) in processing station 3.

In overall etching apparatus 30, an etching solution is supplied to lower surface (Wb) of a wafer (W). As for the etching solution, a mixed solution of hydrogen fluoride and isopropyl alcohol (HF/IPA), a mixed solution of hydrogen fluoride and ethanol, or the like is used. Accordingly, the wafer (W) is etched to have a predetermined thickness (step (S1) in FIG. 9 and FIG. 10(a)). Then, the wafer (W) is transferred to process solution supply apparatus 31 by wafer transfer apparatus 50.

The wafer (W) is transferred to process solution supply apparatus 31 and is held by holding mechanism 72. At this time, the wafer (W) is held by holding mechanism 72 in such a way that its lower surface (Wb) faces downward, namely, lower surface (Wb) faces upper surface (60a) of template 60. Next, template 60 held by spin chuck 62 is rotated while its upper surface (60a) faces upward, namely, opening portions 90 face upward, and all covers 96 are closed. In the meantime, process solution supply nozzle (70a) moves to the center of template 60, and an etching solution as a process solution is dropped from process solution supply nozzle (70a) onto upper surface (60a) of template 60. The etching solution dropped from process solution supply nozzle (70a) is filled in flow channels 91 of template 60 through opening portions 90 (step (S2) in FIG. 9 and FIG. 10(b)). During this time, excess etching solution is spun off from the periphery of template 60 and drained from cup 64 through drainpipe 65. A mixed solution of hydrogen fluoride and isopropyl alcohol (HF/IPA), for example, is used as the etching solution. Here, it is an option for template 60 to be mounted in advance on spin chuck 62 before the wafer (W) is transferred to process solution supply apparatus 31, or to be mounted on spin chuck 62 after the wafer (W) is transferred. Also, the wafer (W) may be transferred to process solution supply apparatus 31 after the etching solution is filled in flow channels 91 of template 60.

When the etching solution is filled in flow channels 91 of template 60 and the excess etching solution is spun off, the rotation of spin chuck 62 is turned off. Next, the positional relationship of the wafer (W) held by holding mechanism 72 and template 60 is adjusted by transport mechanism 73 so that positions of through holes (H) to be formed in the wafer (W) correspond to opening portions 90 of template 60. Then, transport mechanism 73 is lowered so that lower surface (Wb) of the wafer (W) is coupled to the upper surface of template 60 (step (S3) in FIG. 9 and FIG. 10(c)). After that, template 60 and the wafer (W) are transferred to selective etching apparatus 32 by wafer transfer apparatus 50 while maintaining a state mechanically coupled to each other by a clamp not shown in the drawing, for example.

Template 60 and the wafer (W) that were transferred to selective etching apparatus 32 are mounted on mounting base 101 in such a way that lower surface (Wb) of the wafer (W) faces upward, namely, in a vertically inverted state from when the wafer (W) was held by spin chuck 62 of process solution supply apparatus 31 (step (S4) in FIG. 9). At this time, template 60 and the wafer (W) maintain their coupled state.

When template 60 and the wafer (W) are mounted on mounting base 101, positions of circuit board 102 held by holding mechanism 103 and connection terminals 93 formed on lower surface (60b) of template 60 are adjusted by transport mechanism 104 to have a predetermined positional relationship. Then, transport mechanism 104 is lowered so that circuit board 102 makes contact with connection terminals 93 to secure the conduction between circuit board 102 and connection terminals 93 (step (S5) in FIG. 9).

Next, using a power unit (not shown in the drawing) electrically connected to circuit board 102, a predetermined voltage is applied between first electrode 92 and second electrode 94 by setting first electrode 92 as a cathode and second electrode 94 as an anode. Accordingly, electrolytic etching is conducted on the wafer (W). During this time, control unit 110 monitors the value of electric current flowing between first electrode 92 and second electrode 94 when voltage is applied, while transmitting electrical signals to covers 96 through connection terminals 93 and circuit board 102 to conduct an opening operation on covers 96 (step (S6) in FIG. 9 and FIG. 10(d)). Through such an opening operation on covers 96, the air in flow channels 91 is released, air bubbles generated in the wafer (W) during electrolytic etching are promptly removed through flow channels 91, the etching solution descends in a suitable manner, and the etching solution maintains constant contact with the wafer (W).

In addition, at the same time as covers 96 are opened, vibration mechanisms (95a-95d) are turned on and off repeatedly in clockwise order from vibration mechanism (95a) to vibration mechanism (95d) as shown in FIG. 7, for example. Namely, vibration mechanisms are turned on and off in sequence from one mechanism to another in a circular direction. Accordingly, a vortex flow is formed in flow channels 91 and through holes (H) so that the reacted etching solution (L) is replaced with an unreacted etching solution, and fine air bubbles, generated on the surface of the wafer (W) caused by chemical reactions of the etching solution (L) and the wafer (W), are promptly removed from through holes (H) and flow channels 91.

Next, as etching progresses on portions of the wafer (W) corresponding to opening portions 90 of template 60, the thickness of semiconductor wafer (W) is reduced and resistance values change between first electrode 92 and second electrode 94, resulting in a change in the current values monitored by control unit 110. Then, as etching on the wafer (W) further progresses, the etching solution (L) reaches metal layer 11 of the wafer (W) as shown in FIG. 10(e). Accordingly, through holes (H) are formed in the wafer (W), while the resistance value between first electrode 92 and second electrode 94 drops rapidly. Therefore, the current values monitored by control unit 110 also show a rapid drop, becoming lower than the predetermined design value. Accordingly, control unit 110 determines that the etching is complete, and the application of voltage by a power unit (not shown in the drawing) is turned off. Also, control unit 110 operates to close covers 96 and to turn off vibration mechanisms (95a-95d). The etching solution from template 60 stops descending, and the etching process is complete (step (S7) in FIG. 9).

When the process at selective etching apparatus 32 is completed, template 60 and the wafer (W) are transferred again by wafer transfer mechanism 50 to process solution supply apparatus 31.

Template 60 and the wafer (W) that were transferred to process solution supply apparatus 31 are held by spin chuck 62 in such a way that lower surface (Wb) of the wafer (W) faces downward, namely, in a vertically inversed state from when they were mounted on mounting base 101 of selective etching apparatus 32. Next, the wafer (W) and support sheet (S) are held by holding mechanism 72, and the wafer (W) is separated from template 60. Here, it is an option for the wafer (W) to be separated from template 60 at selective etching apparatus 32.

Next, template 60 held by spin chuck 62 is rotated, while process solution supply nozzle (70b) is moved to the center of template 60 so that an insulation film electrocoating solution as a process solution drops from process solution supply nozzle (70b) onto surface (60a) of template 60. Then, the insulation film electrocoating solution that has dropped from process solution supply nozzle (70b) is filled in flow channels 91 of template 60 the same as the etching solution (L) (step (S8) in FIG. 9). At the same time, the excess insulation film electrocoating solution is spun off from the periphery of template 60 and drained from cup 64 through drainpipe 65. Here, a polyimide electrocoating solution, for example, is used as the insulation film electrocoating solution.

The insulation film electrocoating solution (P) is filled in flow channels 91 of template 60, the excess insulation film electrocoating solution is spun off, and then the rotation of spin chuck 62 is turned off. Next, the positions of the wafer (W) held by holding mechanism 72 and template 60 are adjusted by transport mechanism 73 to have a predetermined positional relationship. Then, transport mechanism 73 is lowered so that lower surface (Wb) of the wafer (W) is coupled again to the upper surface of template 60 (step (S9) in FIG. 9 and FIG. 10(f)). After that, template 60 and the wafer (W) are transferred by wafer transfer apparatus 50 to insulation film forming apparatus 33 while maintaining their coupled state.

Template 60 and the wafer (W) that were transferred to insulation film forming apparatus 33 are mounted on mounting base 101, and their positions are adjusted by transport mechanism 104 so that circuit board 102 held by holding mechanism 103 and connection terminals 93 have a predetermined positional relationship. Then, transport mechanism 104 is lowered so that circuit board 102 makes contact with connection terminals 93 and electrical conduction is secured between circuit board 102 and connection terminals 93 (step (S10) in FIG. 9).

Next, first electrode 92 is set as an anode and second electrode 94 as a cathode, and a predetermined voltage is applied between first electrode 92 and second electrode 94 by a power unit (not shown in the drawing) electrically connected to circuit board 102. Accordingly, as shown in FIG. 10(g), insulation film 140 with a uniform thickness is formed on the entire surface of the wafer (W) including through holes (H) formed at selective etching apparatus 32. When insulation film 140 is formed, the supply of the polyimide electrocoating solution (P) and the application of voltage are turned off (step (S11) in FIG. 9). Here, control unit 110 operates to open and close covers 96 with suitable timing, the same as in the above-selective etching.

The wafer (W) with insulation film 140 is separated from template 60 and transferred to insulation film removing apparatus 34 by wafer transfer apparatus 50. Next, using a laser or pulse power, for example, insulation film 140 on bottom portions of through holes (H) is selectively removed from the wafer (W) transferred to insulation film removing apparatus 34 (step (S12) in FIG. 9 and FIG. 10(h)). Here, when insulation film 140 is removed selectively as shown in FIG. 10(h), insulation film 140 on bottom portions of through holes (H) may also be removed selectively by the following method, the same as when a laser or pulse power is used: template 60 with pure water filled in flow channels 91, for example, is coupled again to the wafer (W) with insulation film 140 after step (S11) in FIG. 9; first electrode 92 is set as a cathode and second electrode 94 as an anode, and voltage in an approximate range of 30V to 100V is applied between first electrode 92 and second electrode 94.

Then, the wafer (W) is transferred to metal film deposition apparatus 40 by wafer transfer apparatus 50. In metal film deposition apparatus 40, metal film 141 made of nickel, for example, is formed as a barrier metal on the upper surface of insulation film 140 (step (S12) in FIG. 9). During this time, template 60 with an electrolytic plating solution as a process solution filled in flow channels 91 is coupled to lower surface (Wb) of the wafer (W), the same as in the above-described process of selective etching or forming insulation film, first electrode 92 is set as an anode and second electrode 94 as a cathode, and a predetermined voltage is applied between first electrode 92 and second electrode 94. Also, control unit 110 operates with suitable timing to open and close covers 96. Accordingly, metal film 141 is formed selectively in through holes (H) and their peripheries as shown in FIG. 10(i).

The wafer (W) where metal film 141 is formed at metal film deposition apparatus 40 is transferred by wafer transfer apparatus 50 to connection electrode forming apparatus 41, and is mounted on mounting base 101.

Next, template 60 with an electrolytic plating solution filled as a process solution in flow channels 91 is coupled to lower surface (Wb) of the wafer (W) mounted on mounting base 101, the same as in metal film deposition apparatus 40, first electrode 92 is set as an anode and second electrode 94 as a cathode, and a predetermined voltage is applied between first electrode 92 and second electrode 94. Also, control unit 110 operates with suitable timing to open and close covers 96 and to drive vibration mechanisms (95a-95d). Accordingly, connection electrodes 142 are formed in through holes (H) as shown in FIG. 10(i).

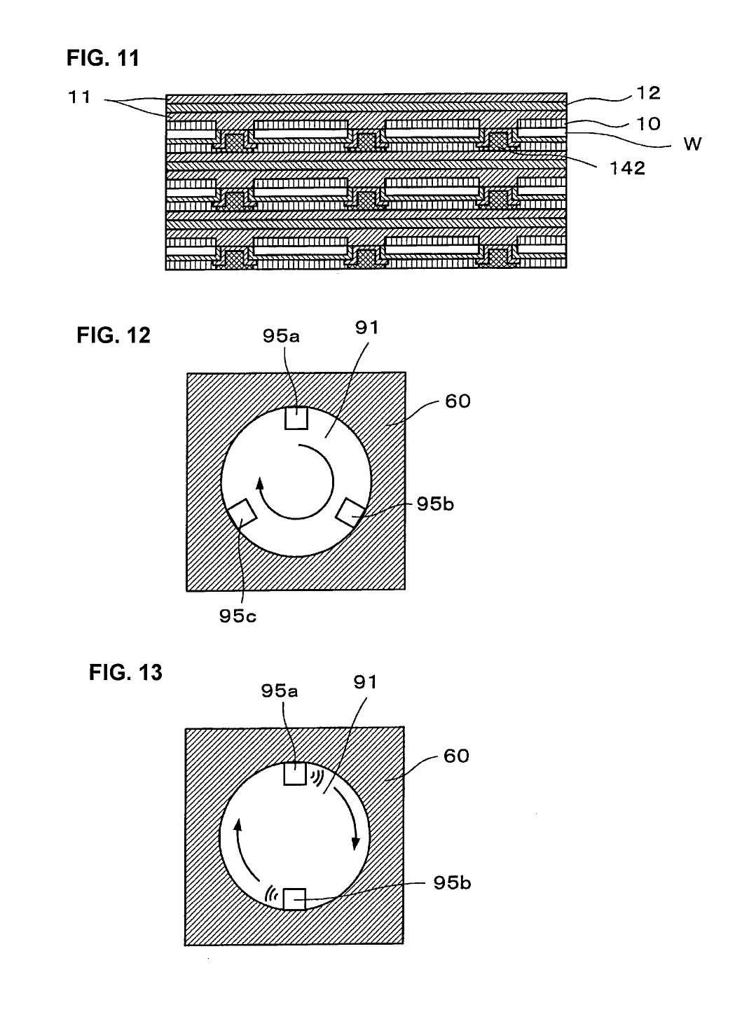

The wafer (W) with connection electrodes 142 is transferred to cassette station 2 by wafer transfer apparatus 50. The wafer (W) accommodated in a cassette (C) of cassette station 2 is transferred to a support sheet removing apparatus (not shown in the drawing) provided outside so that the support sheet (S) is removed from the wafer (W) at the support sheet removing apparatus. Then, the wafer (W) is inspected by an inspection apparatus (not shown in the drawing), and the wafer (W) is laminated on other wafers (W) at a wafer lamination apparatus (not shown in the drawing) so that a semiconductor device is formed with three-dimensionally laminated wafers as shown in FIG. 11.

According to the above embodiment, an etching solution is filled in flow channels 91 of a template where opening portions 90 are formed in a predetermined pattern, lower surface (Wb) of a wafer (W) is coupled to upper surface (60a) of template 60, and then the air inside flow channels 91 is released by opening covers 96 formed on lower surface (60b) of template 60 so that etching solution (L) is supplied from opening portions 90 to the wafer (W). Accordingly, etching is conducted selectively in a predetermined pattern on positions of the wafer (W) corresponding to opening portions 90. Therefore, high-cost dry etching is not required for forming through holes (H) in a wafer (W). In addition, since template 60 is used instead of a conventional mask formed by photolithography, a step for forming a mask for each wafer (W) is eliminated. Accordingly, throughput is enhanced when lower surface (Wb) of a wafer (W) is selectively etched, and the cost is reduced. Moreover, apparatuses for forming masks, such as an application and development apparatus to apply resist and conduct a development treatment as well as an exposure apparatus to conduct an exposure treatment on the resist, are also eliminated. Thus, an apparatus for forming through holes (H) is simplified. In addition, opening portions 90 of template 60 are formed all at once with high positional accuracy by conducting a photolithographic process and an etching process, for example. Thus, conventionally experienced challenges such as aligning microprobes with high positional accuracy will not occur. Accordingly, using the present embodiment, multiple through holes (H) are formed with high positional accuracy through wet etching.

Also, process solution supply apparatus 31 to be used when an etching solution is filled in template 60 has the same structure as a so-called application process apparatus conventionally used when a resist solution or the like is applied on a wafer (W). Thus, implementing the method of the present embodiment does not require any specific apparatus, and a low-cost method is provided for supplying process solutions.

Also, since a vortex on a planar view is generated in flow channels 91 using vibration mechanisms (95a-95d) positioned in concentric circles on the inner surfaces of flow channels 91, air bubbles in flow channels 91 and through holes (H) are promptly removed, while the etching solution descends in a suitable manner, maintaining constant contact between the unreacted etching solution and the wafer (W). Accordingly, the etching rate is enhanced, and the throughput of the etching process is improved.

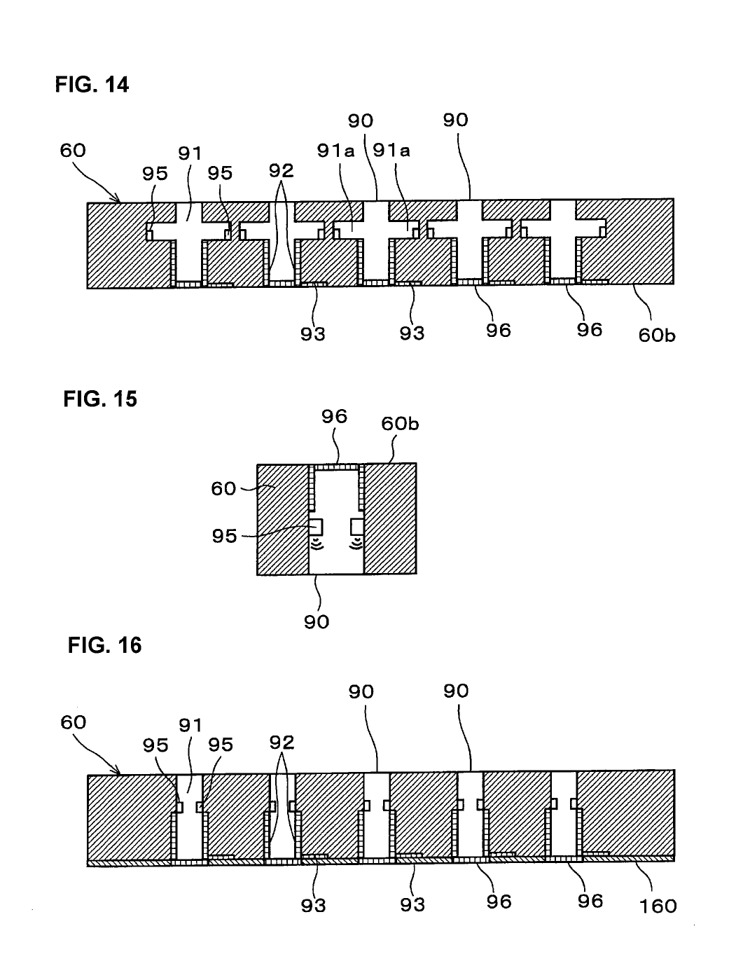

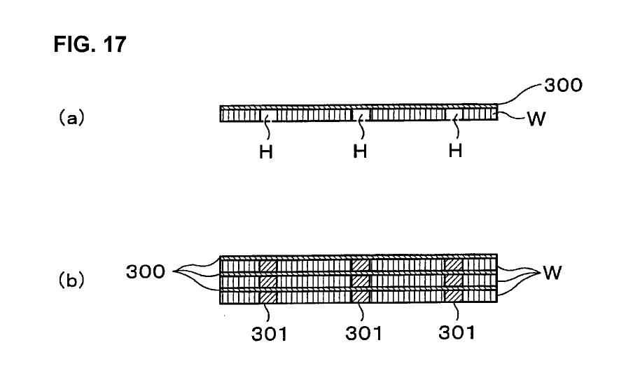

The above embodiment described an example where four vibration mechanisms (95a-95d) are positioned in concentric circles on the inner surface of flow channel 91. However, when forming a vortex flow using vibration mechanisms, three vibration mechanisms (95a-95c) may also be positioned in concentric circles as shown in FIG. 12, for example. Alternatively, two vibration mechanisms (95a, 95b) may be positioned facing each other to form vibrations in a circular direction for the etching solution as shown in FIG. 13, for example. Any setting may be employed as long as a vortex flow is formed in flow channel 91. In addition, to form a vortex flow efficiently in flow channel 91, an enlarged portion (91a) may be formed in a flow channel 91 to have a larger diameter than the rest of the flow channel 91 as shown in FIG. 14, for example, and vibration mechanisms 95 may be positioned in such enlarged portion (91a).

Also, to remove air bubbles by vibration mechanisms 95, namely, to replace the reacted etching solution with an unreacted etching solution, the flow of the etching solution by vibration mechanisms 95 is not necessarily a vortex flow. For example, as shown in FIG. 15, vertically downward vibrations may also be provided to through holes (H).

According to the above embodiment, the value of electric current flowing between first electrode 92 as a cathode and second electrode 94 as an anode is monitored by control unit 110 during electrolytic etching. Therefore, the progress of etching, namely, the completion timing of the etching, is precisely determined by a change in current values. Accordingly, insufficient etching or excess etching will not occur. For that matter, in conventional dry etching such as plasma etching, etching depth was controlled by the duration of the etching process based on the etching rate provided in the etching apparatus. Therefore, if the etching does not progress at the initial rate, it may result in insufficient etching and cause incomplete formation of through holes (H), or conversely, it may result in excess etching and cause damage to metal layer 11 or insulation layer 12, for example. However, according to the present invention, the completion timing of the etching is precisely determined by monitoring the progress of the etching. Thus, the supply of the etching solution is turned off by a closing operation on covers 96 when etching is completed. Accordingly, using the etching method of the present invention, conventionally experienced problems such as insufficient or excess etching will not occur. Here, the method for monitoring the progress of a process through a change in current values may also be employed when applying voltage between an anode and a cathode, for example. In the present embodiment, such a monitoring method may also be employed when insulation film 140 is formed using an insulation film electrocoating solution, when metal film 141 is formed through electrolytic plating, and so forth.

In the above embodiment, it is an option to apply a hydrophobic treatment to upper surface (60a) of template 60 so that the etching solution is prevented from leaking from flow channels 91 to outside template 60 during the etching process. In such a case, if the same treatment as applied to upper surface (60a) of template 60 is also applied to lower surface (Wb) of a wafer (W) except for those portions corresponding to opening portions 90 of template 60, the process solution filled in flow channels 91 will not spread on portions of lower surface (Wb) of the wafer (W) other than those that correspond to opening portions 90, even if the tight adhesion between template 60 and the wafer (W) is not perfect and there is a small gap existing between them. Accordingly, the etching solution is prevented from being supplied to portions other than the predetermined portions of the wafer (W), thus securely preventing unwanted etching on portions where etching is not required.

In the above embodiment, covers 96 are provided on lower surface (60b) of template 60 to individually cover each flow channel 91. However, as shown in FIG. 16, for example, water sealing film 160 may be provided to cover the entire lower surface (60b) of template 60 to cover all flow channels 91. In such a case, electrical circuits are formed on water sealing film 160 to be electrically connected to connection terminals 93, and circuit board 102 makes contact with water sealing film 160 so as to secure electrical connection between first electrodes 92 and circuit board 102. To release air from flow channels 91, water sealing film 160 may be lifted entirely so that the air is released from the entire template 60, or individual covers 96 may be provided to water sealing film 160.

In the above embodiment, template 60 is formed in a disc shape with flow channels 91 formed inside. However, template 60 is not always required to be in a disc shape, and it may be in a rectangular shape, for example.

In the above embodiment, the same template 60 is used to supply process solutions when etching a wafer, forming an insulation film, and forming metal film respectively. However, opening portions 90 are not required to be formed in the same positions of a template to be used in each process. In particular, by setting the number of opening portions of a template for supplying an etching solution to be greater than that of the opening portions of a template for supplying an electrolytic plating solution, through holes (H) without connection electrodes 142 may be formed in a wafer (W). In such a case, through holes (H) without connection electrodes 142 may be used for dissipating heat from a device formed on the wafer (W), or may be used as through holes (H) for forming backup electrodes, or may be used as scribe lines.

In the above embodiment, a process solution is supplied by template 60 once for each step. However, when a process solution is supplied to a larger substrate such as an FPD (flat panel display) instead of a wafer (W), etching may be conducted repeatedly portion by portion by moving template 60 so that through holes (H) are formed on the entire FPD. Also, when through holes (H) are formed chip by chip on a wafer (W), etching may be conducted repeatedly on the wafer (W) while moving template 60.

In the above embodiment, hydrogen fluoride and isopropyl alcohol are used as the etching solution for a wafer (W). However, for example, a mixed solution of hydrogen fluoride and nitric acid may also be used. In such a case, first electrode 92 and second electrode 94 may be omitted in template 60. Also, if the etching target is silicon oxide (SiO) film or silicon nitride (SiN) film formed on a wafer (W), buffered hydrogen fluoride (HF/NH₄HF) or phosphoric acid (H₃PO₄) may also be used as an etching solution (L), for example. In such a case as well, first electrode 92 and second electrode 94 may be omitted.

So far, a preferred embodiment of the present invention is described by referring to the attached drawings. However, the present invention is not limited to such examples. The present invention is also applicable to other substrates such as FPDs (flat panel displays) or reticles for photomasks in addition to wafers.

The present invention is effective when selectively etching substrates.

An embodiment of the present invention is a method for selectively etching a substrate in a predetermined pattern by supplying an etching solution to the substrate. Such a method includes the following: coupling the substrate to an upper surface of a template where multiple opening portions are formed on the upper surface to correspond to the predetermined pattern, flow channels are formed to penetrate from the opening portions to a lower surface, multiple openable/closable covers to cover the flow channels are formed at the ends of the flow channels opposite the opening portions, and an etching solution is filled in each flow channel; supplying the etching solution to the substrate through the opening portions by releasing the air in each flow channel when the covers are opened; and vibrating the etching solution by driving vibration mechanisms positioned on the inner surfaces of flow channels of the template when supplying the etching solution. In such a method, the vibration mechanisms are positioned in such a way that the etching solution forms a vortex on a planar view in the flow channels.

According to an embodiment of the present invention, a substrate is coupled to an upper surface of a template where opening portions are formed in a predetermined pattern and an etching solution is filled in flow channels, and then the etching solution is supplied to the substrate from the opening portions by opening the covers formed on the lower surface of the template to release the air in the flow channels. Accordingly, the substrate is selectively etched in a predetermined pattern corresponding to the opening portions. Therefore, high-cost dry etching is not required for forming through holes in the substrate. In addition, since a template is used instead of a conventional method of using a mask formed by photolithography, a step for forming a mask for each substrate is not necessary. Accordingly, throughput is enhanced when selectively etching a substrate, while cost is reduced. Furthermore, since the opening portions of a template are formed all at once with high positional accuracy by conducting a photolithographic process and an etching process, for example, challenges such as aligning the positions of microprobes highly accurately are not presented as they were when using conventional technology. Therefore, according to the present embodiment, multiple through holes (H) are formed with high positional accuracy through wet etching.

In addition, a vortex flow is generated in the flow channels by vibration mechanisms positioned on the inner surfaces of the flow channels. Thus, air bubbles inside the flow channels and through holes are removed promptly, while the etching solution is descended in a suitable manner so that contact between the unreacted etching solution and the substrate is constantly maintained. Accordingly, the etching rate is enhanced and the throughput of the etching process is improved.

Another aspect of the present invention is a computer readable recording medium with a stored program that operates on a computer in a control unit for controlling a substrate processing system to implement a method for selectively etching a substrate in a predetermined pattern by supplying an etching solution to a substrate using the substrate processing system. The method for etching a substrate includes the following: coupling the substrate to an upper surface of a template where multiple opening portions are formed on the upper surface to correspond to the predetermined pattern, flow channels are formed to penetrate from the opening portions to a lower surface, an openable/closable cover to cover each flow channel is formed at the end of each flow channel opposite the opening portion, and an etching solution is filled in each flow channel; supplying the etching solution to the substrate through the opening portions by releasing the air in each flow channel when the cover is opened; and vibrating the etching solution by driving vibration mechanisms positioned on the inner surfaces of the flow channels of the template when supplying the etching solution. In such a method, the vibration mechanisms are positioned in such a way that the etching solution forms a vortex on a planar view in the flow channels.

According to an embodiment of the present invention, etching is conducted on predetermined positions of a substrate with high positional accuracy by using a low-cost method.

Obviously, numerous modifications and variations of the present invention are possible in light of the above teachings. It is therefore to be understood that within the scope of the appended claims, the invention may be practiced otherwise than as specifically described herein.

What is claimed is:

1. A method for selectively etching a substrate, comprising:
providing a template having a plurality of opening portions formed on an upper surface in a predetermined pattern and a plurality of flow channels penetrating through the template from the opening portions to a lower surface of the template;
filling an etching solution into the flow channels;
coupling the upper surface of the template to a substrate such that the plurality of opening portions corresponds to the predetermined pattern of a plurality of through holes to be formed through the substrate; and
supplying the etching solution onto the substrate through the opening portions of the template such that the plurality of through holes is etched through the substrate.

2. The method for selectively etching a substrate according to claim 1, further comprising:
applying voltage through the etching solution during the supplying of the etching solution; and
determining completion of an etching process based on a value of current flowing through the etching solution such that the plurality of through holes is formed in the substrate.

3. The method for selectively etching a substrate according to claim 2, further comprising:
measuring change in the current flowing through the etching solution during the supplying of the etching solution; and
monitoring progress of the etching process based on the value of current.

4. The method for selectively etching a substrate according to claim 1, further comprising applying a hydrophobic treatment on the substrate except for portions corresponding to the opening portions of the template, wherein the template has the upper surface which has a hydrophobic treatment.

5. The method for selectively etching a substrate according to claim 2, wherein the template has an insulative body comprising an insulative material and has a first electrode formed on a surface of each of the flow channels of the template, the substrate has a second electrode formed on a surface of the substrate facing the template in contact with the substrate, and the applying of voltage comprises applying voltage between the first electrode and the second electrode.

6. The method for selectively etching a substrate according to claim 1, wherein the template has a plurality of covering devices configured to open the flow channels at end portions of the flow channels on the lower surface of the template, and the supplying of the etching solution comprises opening the covering devices at the end portions of the flow channels such that the etching solution is supplied onto the substrate through the opening portions of the template.

7. The method for selectively etching a substrate according to claim 1, further comprising vibrating the etching solution such that the etching solution forms vortexes in the flow channels during the supplying of the etching solution.

8. A method for selectively processing a substrate, comprising:
providing a template having a plurality of opening portions formed on an upper surface in a predetermined pattern and a plurality of flow channels penetrating through the template from the opening portions to a lower surface of the template;
coupling the upper surface of the template to a substrate having a plurality of through holes formed through the substrate such that the plurality of opening portions corresponds to the predetermined pattern of the plurality of through holes in the substrate; and
supplying a processing solution into the plurality of through holes formed in the substrate through the opening portions of the template such that the processing solution deposits a plurality of films in the plurality of through holes, respectively.

9. The method for selectively processing a substrate according to claim 8, further comprising:
applying voltage through the processing solution during the supplying of the processing solution; and
determining completion of a deposition process based on a value of current flowing through the processing solution such that the plurality of films is formed in the plurality of through holes, respectively.

10. The method for selectively processing a substrate according to claim 9, further comprising:
measuring change in the current flowing through the processing solution during the supplying of the processing solution; and
monitoring progress of the deposition process based on the value of current.

11. The method for selectively processing a substrate according to claim 8, further comprising applying a hydrophobic treatment on the substrate except for portions corresponding to the opening portions of the template, wherein the template has the upper surface which has a hydrophobic treatment.

12. The method for selectively processing a substrate according to claim 9, wherein the template has an insulative body comprising an insulative material and has a first electrode formed on a surface of each of the flow channels of the template, the substrate has a second electrode formed on a surface of the substrate facing the template in contact with the substrate, and the applying of voltage comprises applying voltage between the first electrode and the second electrode.

13. The method for selectively processing a substrate according to claim 8, wherein the template has a plurality of covering devices configured to open the flow channels at end portions of the flow channels on the lower surface of the template, and the supplying of the processing solution comprises opening the covering devices at the end portions of the flow channels such that the processing solution is supplied into the plurality of through holes in the substrate through the opening portions of the template.

14. The method for selectively processing a substrate according to claim 8, wherein the processing solution is one of an insulation film electrocoating solution and an electrolytic plating solution, and the plurality of films is one of a plurality of insulation films and a plurality of plated metal films.

15. A selective etching apparatus, comprising:
a processing vessel;
a template accommodated in the processing vessel and having a plurality of opening portions formed on an upper surface of the template and a plurality of flow channels penetrating through the template from the opening portions to a lower surface of the template; and
a mounting base accommodated in the processing vessel and configured to mount a substrate and the template,
wherein the flow channels of the template are configured to be filled with an etching solution, the plurality of opening portions is positioned on the upper surface in a predetermined pattern, and the upper surface of the template is configured to be coupled to a surface of the substrate such that the plurality of opening portions corresponds to the predetermined pattern of a plurality of through holes to be formed through the substrate.

16. The selective etching apparatus according to claim 15, further comprising a plurality of vibration mechanisms positioned circumferentially on an inner surface of each of the flow channels, wherein the plurality of vibration mechanisms is configured to vibrate the etching solution such that the etching solution forms vortexes in the flow channels.

17. The selective etching apparatus according to claim 16, wherein the template has a plurality of covering devices configured to open the flow channels at end portions of the flow channels on the lower surface of the template, and the plurality of covering devices is configured to open the flow channels such that the etching solution is supplied onto the substrate through the opening portions of the template and that the plurality of through holes is etched through the substrate.

18. The selective etching apparatus according to claim 15, wherein the template has the upper surface which has a hydrophobic treatment.

19. The selective etching apparatus according to claim 15, further comprising:
a voltage applying device configured to apply voltage through the etching solution;
a current measuring device configured to measure a value of current flowing through the etching solution; and
a controlling device configured to determine completion of an etching process based on the value of current.

20. The selective etching apparatus according to claim 19, wherein the template has an insulative body comprising an insulative material and has a first electrode formed on a surface of each of the flow channels of the template, the substrate has a second electrode formed on a surface of the substrate facing the template in contact with the substrate, and the voltage applying device is configured to apply the voltage between the first electrode and the second electrode.
